(19) United States
(12) Patent Application Publication
(10) Pub. No.: US 2022/0139990 A1
(43) Pub. Date: May 5, 2022

(54) POLARIMETRIC IMAGING CAMERA

(71) Applicant: Facebook Technologies, LLC, Menlo Park, CA (US)

(72) Inventors: Qing Chao, Redmond, WA (US); Xinqiao Liu, Medina, WA (US)

(21) Appl. No.: 17/514,286

(22) Filed: Oct. 29, 2021

Related U.S. Application Data
(60) Provisional application No. 63/109,704, filed on Nov. 4, 2020.

(51) Int. Cl. H01L 27/146; H04N 5/232; H04N 5/225; G02B 27/01; G02B 3/04; G02B 1/08

(52) U.S. Cl. CPC H01L 27/14627; H04N 5/23229; H04N 5/2257; G02B 27/0172; G02B 2027/0138; G02B 1/08; H01L 27/1463; G02B 2027/0178; G02B 3/04

(57) ABSTRACT

In one example, an apparatus comprises: a semiconductor substrate comprising a first photodiode and a second photodiode, the first photodiode being positioned adjacent to the second photodiode along a first axis; a birefringent crystal positioned over the first photodiode and the second photodiode along a second axis perpendicular to the first axis; and a microlens positioned over the birefringent crystal along the second axis, the microlens having an asymmetric curvature along the first axis, an apex point of the curvature being positioned over the first photodiode along the second axis.

### CROSS-REFERENCE TO RELATED APPLICATIONS

This application claims the benefit of U.S. Provisional Application No. 63/109,704, filed Nov. 4, 2020, entitled “POLARIMETRIC IMAGING CAMERA,” which is incorporated herein by reference in its entirety.

### BACKGROUND OF THE INVENTION

Polarimetric imaging allows an image of a scene to be generated that can reveal details that may be difficult to discern or that are simply not visible in regular monochromatic, color, or infrared (IR) images, which may only rely on intensity or wavelength properties of light. By extracting information relating to the polarization of the received light, more insights can potentially be obtained from the scene. For example, a polarimetric image of an object may uncover details such as surface features, shape, shading, and roughness with high contrast. Though polarimetric imaging has some implementation in industry (e.g., using a wire grid polarizer on a sensor chip), polarimetric imaging has mainly been used in scientific settings and required expensive and specialized equipment. Even when such equipment is available, existing techniques for polarimetric imaging can involve time-division or space-division image capture, which can be associated with blurring in either the time or space domain. There exists a significant need for an improved system for polarimetric imaging.

### BRIEF DESCRIPTION OF THE DRAWINGS

Illustrative examples are described with reference to the following figures.

FIG. 1 illustrates different types of polarization of light

FIG. 2 and FIG. 3 present examples of the effect of polarizers on light reflecting from different surfaces.

FIG. 4 illustrates examples of images captured or computed based on different properties of light.

FIG. 5A illustrates an example of a linear polarizer. FIG. 5B illustrates an example of a 4 by 1 linear polarizer array.

FIG. 6A, and FIG. 6B illustrate two examples of birefringent materials as polarizers.

FIG. 7A illustrates an embodiment of a sensor controller layout for an image sensor 700 that can perform measurements of polarized light.

FIG. 7B illustrates an embodiment of a sensor optics layout for the image sensor that can perform measurements of polarized light

FIG. 7C depicts a relationship between multiple image frames generated from the image sensor during one exposure period.

FIG. 8A is a side view of an embodiment of a pixel cell.

FIG. 8B is a top view of an embodiment of a pixel cell.

FIG. 8C is a side view of an embodiment of a pixel cell focusing light using a microlens.

FIG. 8D is a side view of an embodiment of a pixel cell showing how depth of a birefringent crystal affects lateral separation of optical components of incident light.

FIG. 9A illustrates top view of embodiments of pixel cells showing locations of an apex and flat portions of microlenses.

FIG. 9B is a side view of an embodiment of a pixel cell with a microlens having one or more flat portions.

FIG. 9C illustrates example arrays of pixel cells.

FIG. 10 illustrates an example of a mobile device that can include one or more polarimetric sensor arrays, according to the disclosed techniques.

FIG. 11 presents a block diagram showing an internal view of some of the main components of the mobile device of FIG. 10.

FIG. 12 illustrates a flowchart of an embodiment of a process for detecting polarized light.

The figures depict examples of the present disclosure for purposes of illustration only. One skilled in the art will readily recognize from the following description that alternative examples of the structures and methods illustrated may be employed without departing from the principles, or benefits touted, of this disclosure.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION OF THE INVENTION

### Polarization of Light

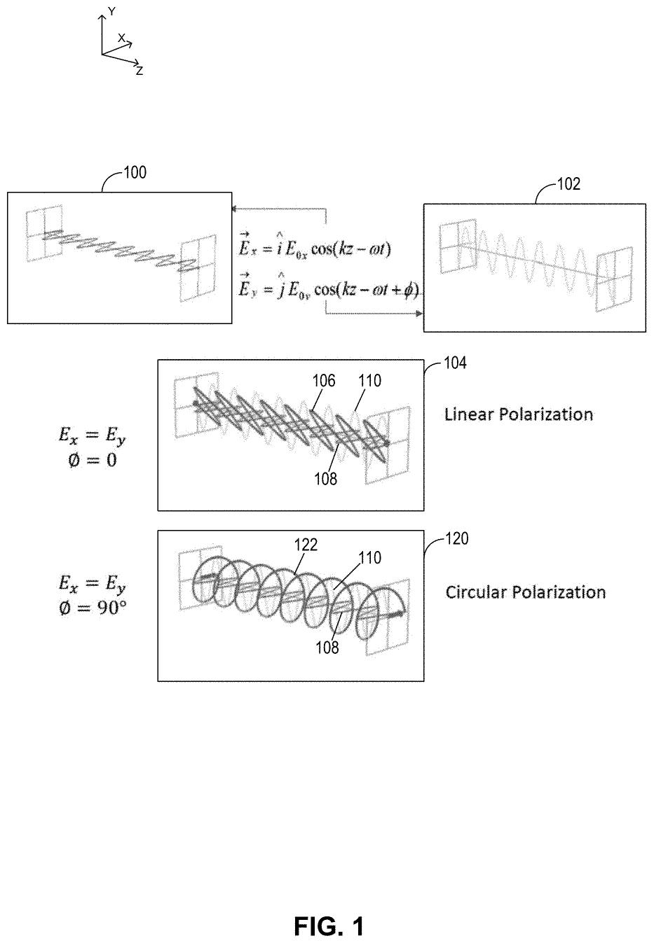

FIG. 1 illustrates different types of polarization of light as an electromagnetic transverse wave traveling along a Z axis. While an electromagnetic wave comprises synchronized oscillations of both an electric and a magnetic field, FIG. 1 only shows the electric field for ease of illustration. A magnetic field having an orientation perpendicular to the electric field is understood to be present. Graph 100 shows the propagation of a “horizontally” polarized electromagnetic wave with oscillations along an X axis. The horizontally polarized wave can be expressed as: \vec{E}ₓ=\hat{ι}Eₒₓ cos(kz−ωt). Graph 102 shows a “vertically” polarized electromagnetic wave oscillating along a Y axis. The vertically polarized wave can be expressed as: \vec{E}_{Y}=\hat{ι}E_{oY} cos(kz−ωWt+∅).

In addition, graph 104 shows a linearly polarized electromagnetic field 106 represented as a combination of a horizontal component of the electric field, \vec{E}ₓ, 108 and a vertical component of the electric field, \vec{E}_{Y}, 110, with no phase offset between the two fields. Such a linearly polarized electromagnetic wave can be expressed as: \vec{E}ₓ+\vec{E}_{Y}, ∅=0. For ease of illustration, the magnitudes of the horizontal and vertical components of the electric field are presented as being equal, i.e., Eₓ=E_{Y}, which results in a linearly polarized wave oscillating along a 45-degree line between the X axis and the Y axis. If the magnitudes of the horizontal and vertical components of the electric field were not equal, the resulting linearly polarized electromagnetic field 106 would oscillate along a line that forms an angle of arctan(E_{y}/Eₓ) relative to the X and Y axes.

Further, graph 120 shows a circularly polarized electromagnetic field 122 represented as the combination of the horizontal component of the electric field 106 and the vertical component of the electric field 110, with a 90-degree phase offset between the two components of the electric field. The circularly polarized electromagnetic field 122 can be expressed as: \vec{E}ₓ+\vec{E}_{Y}, ∅=90°.

More generally speaking, an elliptically polarized electromagnetic wave is generated if a different phase offset is applied. In fact, to be precise, “elliptical” polarization is the most general term used to describe an electromagnetic wave expressed as: \vec{E}ₓ+\vec{E}_{Y}, ∅=X. “Linear” polarization can be viewed as a special case of elliptical polarization, with ∅ taking on the value of 0. “Circular” polarization can be viewed as a special case of elliptical polarization, with ∅ taking on the value of 90 degrees.

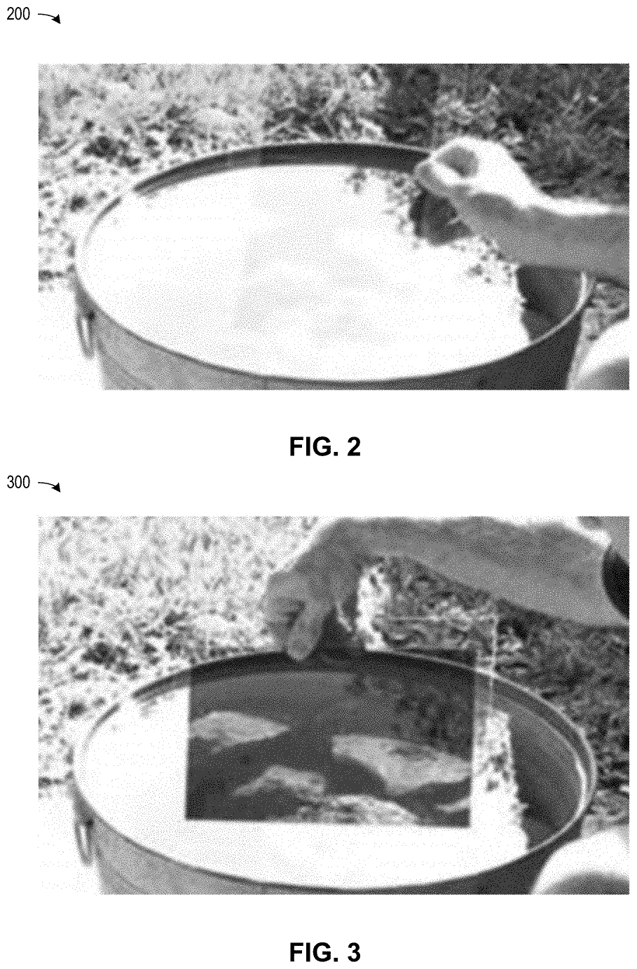

FIG. 2 and FIG. 3 present examples of the effect of polarizers on light reflecting from different surfaces. In these examples, a viewer observes a scene comprising a vat filled with water, with stones submerged beneath the surface of the water. In diagram 200 a horizontally oriented linear polarizer is placed between the scene and the viewer. Light from the scene must pass through the polarizer to reach the eyes of the viewer. The horizontally oriented linear polarizer acts as a filter, to let horizontally polarized light through but filter out vertically polarized light. On a bright day, what the viewer sees from the scene can include light reflecting off of the stones as well as light reflecting off of the surface of the water (i.e., glare). Generally speaking, when light strikes a surface, the reflected light waves are polarized to match the angle of that surface. Thus, a highly reflective horizontal surface, such as the surface of the water, produces predominately horizontally polarized light. As diagram 200 shows, a horizontally oriented polarizer does almost nothing to block the glare (horizontally polarized light) coming off of the surface of the water. The glare is so strong that it is difficult for the viewer to see the light reflecting off of stones submerged beneath the surface of the water.

In diagram 300, the same linear polarizer is rotated 90 degrees, such that it is now vertically oriented. The vertically oriented linear polarizer acts as a filter, to let vertically polarized light through but filter out horizontally polarized light. The vertically oriented linear polarizer blocks the glare (horizontally polarized light) coming off of the surface of the water. With the glare removed, the viewer can now see the light reflecting off of the stones submerged beneath the surface of the water. In other words, the stones are now visible to the viewer. Diagrams 200 and 300 thus illustrate the operation of polarizers to block light and/or let light pass through, depending on orientation of polarization. While only linear polarizers are illustrated in diagrams 200 and 300, other types of polarizers such as circular or elliptical polarizers can also operate to filter light based on polarization.

### Stokes Vector

The Stokes vector S, which characterizes the polarization state of a beam of light, can be defined as:

$$S = ( \begin{matrix}{S}_{0} \\ {S}_{1} \\ {S}_{2} \\ {S}_{3}\end{matrix} ) = ( \begin{matrix}{I}_{H} + {I}_{V} \\ \begin{matrix}{I}_{H} - {I}_{V} \\ {I}_{+ 45} - {I}_{- 45} \\ {I}_{RHC} - {I}_{LHC}\end{matrix}\end{matrix} ) = ( \begin{matrix}〈 {E}_{H} {E}_{H}^{*} + {E}_{V} {E}_{V}^{*} 〉 \\ 〈 {E}_{H} {E}_{H}^{*} - {E}_{V} {E}_{V}^{*} 〉 \\ 〈 {E}_{H} {E}_{V}^{*} + {E}_{V} {E}_{H}^{*} 〉 \\ 〈 i ( {E}_{H} {E}_{V}^{*} + {E}_{V} {E}_{H}^{*} ) 〉\end{matrix} )$$

The stokes vector S consists of four separate Stokes parameters, including an intensity Stokes parameter S₀ and three polarization Stokes parameters S₁, S₂, and S₃. Each of the four Stokes parameters can be expressed as a particular combination of one or more of six distinct polarization intensity values, which represent six distinct states of polarization (SoPs). The six SoP intensity values include: (1) I_{H}, intensity of the light along the direction of horizontal polarization (e.g., along the X-axis of FIG. 1), (2) I_{V}, intensity of the light along the direction of vertical polarization (e.g., along the Y-axis of FIG. 1), (3) I₊₄₅, intensity of the light along the positive 45-degree linear polarization, (4) I₋₄₅, intensity of the light along the negative 45-degree linear polarization, (5) I_{RHC}, intensity of the light along the right-handed circular polarization, and (6) I_{LHC}, intensity of the light along the left-handed circular polarization. These six polarization intensity values can, in turn, be expressed as multiplications of various complex amplitudes (and their complex conjugates) of the electromagnetic field of the light along the horizontal and vertical polarization axes. The first four polarization intensity values, including I_{H}, I_{V}, I₊₄₅, and I₋₄₅, can be measured using four linear polarizers. Moreover, the last two polarization intensity values, including I_{RHC} and I_{LHC}, can be measured using two circular polarizers.

The first Stokes parameter, S₀, expressed as I_{H}+I_{V}, is the overall intensity parameter and represents the total intensity of the light. The second Stokes parameter, S₁, expressed as I_{H}−I_{V}, is a measure of the relative strength of the intensity of the light along the horizontal polarization over the vertical polarization. The third Stokes parameter, S₂, expressed as I₊₄₅−I₋₄₅, is a measure of the relative strength of the intensity of the light along the positive 45-degree linear polarization over the negative 45-degree linear polarization. The fourth Stokes parameter, S₃, expressed as I_{RHC}−I_{LHC}, is a measure of the relative strength of the intensity of the light along the right-handed circular polarization over the left-handed circular polarization. There are other representations of the Stokes Vector S and corresponding Stokes parameters S₀, S₁, S₂, and S₃. Whatever the format used, the Stokes vector S serves to characterize the polarization state of a beam of light.

Different measures of degree of polarization can be expressed as functions of various Stokes parameters discussed above. The total degree of polarization (DoP) may be expressed as:

$$D o P = \frac{\sqrt{{S}_{1}^{2} + {S}_{2}^{2} + {S}_{3}^{2}}}{{S}_{0}} \qquad ( Equation 1 )$$

In Equation 1, DoP can represent the ratio of the combined magnitude of all three polarization Stokes parameters, S₁, S₂, and S₃ as compared to the magnitude of the intensity Stokes parameter S₀.

The degree of linear polarization (DoP_{L}) may be expressed as:

$$D o {P}_{L} = \frac{\sqrt{{S}_{1}^{2} + {S}_{2}^{2}}}{{S}_{0}} \qquad ( Equation 2 )$$

In Equation 2, DoP_{L} represents the ratio of the combined magnitude of the two linear polarization Stokes parameters, S₁ and S₂ as compared to the magnitude of the intensity Stokes parameter S₀.

The degree of circular polarization (DoP_{C}) may be expressed as:

$$D o {P}_{C} = \frac{{S}_{3}}{{S}_{0}} \qquad ( Equation 3 )$$

In Equation 3, DoP_{C} represents the ratio of the magnitude of the circular polarization Stokes parameter, S₃, as compared to the magnitude of the intensity Stokes parameter S₀. These three different types of “degree of polarization” are useful measures that represent the degree to which the light beam in question is polarized (DoP), linearly polarized (DoP_{L}), or circularly polarized (DoP_{C}).

The Angle of Circular Polarization (AoCP) may be expressed as:

$$A o C P = \frac{1}{2} acr tan \frac{{S}_{2}}{{S}_{1}} \qquad ( Equation 4 )$$

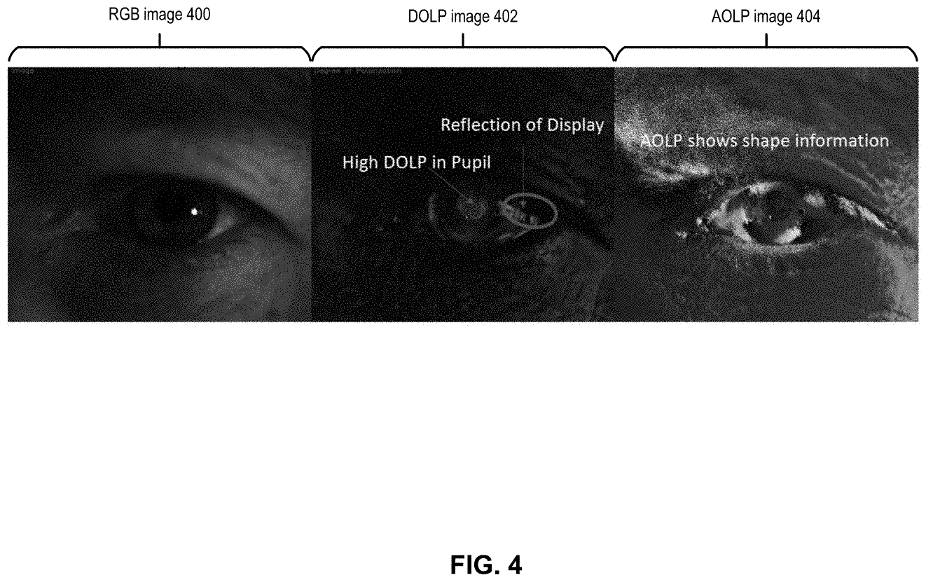

FIG. 4 illustrates examples of images 400, 402, and 404 captured based on different properties of light. In FIG. 4, image 400 can include a conventional red-green-blue (RGB) image. Such an RGB image can represent a distribution of intensities of light in each of three wavelength ranges, i.e., wavelength ranges associated with the colors red, green, and blue, respectively, among the pixels of image 400. Thus, the RGB image is an image based on intensity and wavelength properties of the light received from the scene.

In addition, image 402 can represent a distribution of a degree of linear polarization (DOLP) image among the pixels of image 402. Here, the degree of linear polarization is expressed as:

DOLP=\sqrt{S₁¹+S₂²} (Equation 5)

In Equation 5, DOLP includes the second Stokes parameter S₁ and the third Stokes parameter S₂. Note that Equation 5 is slightly different than the degree of linear polarization (DoP_{L}) of Equation 2. Nevertheless, the DOLP expression provides a representation of the degree to which the light received from the scene is linearly polarized. In image 404, the value of each pixel can measure the DOLP value of the light associated with that pixel. A measure of the degree of polarization, such as DOLP, is particularly useful in extracting information regarding reflections of light. For example, as shown in FIG. 4, image 402 can include high DOLP values for the pupil region (which is highly reflective) of the eye, as well as high DOLP values for the reflection of a display seen on the surface of the eye.

Image 404 can include an angle of linear polarization (AOLP) image. Here, the angle of linear polarization is expressed as:

AOPL=arctan(S₂/S₁) (Equation 6)

A measure of the angle of linear polarization is useful in computing shape information of the eye (e.g., using a further compute algorithm to calculate the spherical shape of the eye). RGB image 400, DOLP image 402, and AOLP image 404 demonstrate examples of how various measures of polarization of light can reveal different types of information about a scene.

### Extraction of Polarized Light Components

To obtain DOLP image 402 and AOLP image 404, an image sensor can include a polarizer to separate out linear polarized light components from non-polarized light components of incident light. The image sensor can also include multiple light sensing elements (e.g., photodiodes) to obtain a spatial distribution of intensities of the linear polarized light component to obtain the Stokes parameters S₁ and S₂, and generate DOLP and/or AOLP pixel values based on Equations 4 and 5. The polarizer can extract, for example, horizontally polarized light to obtain intensity value I_{H}, vertically polarized light to obtain intensity value I_{V}, as well as light having 45-degree linear polarization to obtain intensity values I₊₄₅ and I₋₄₅.

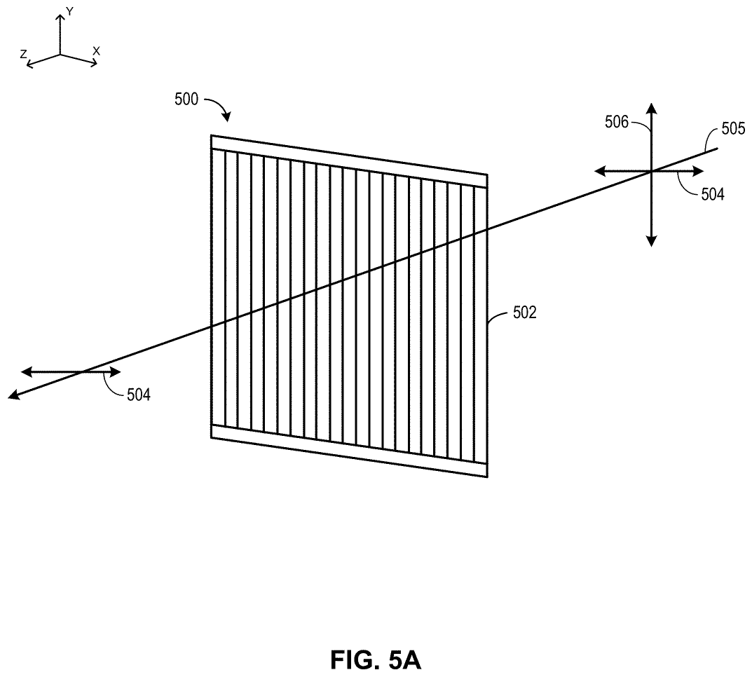

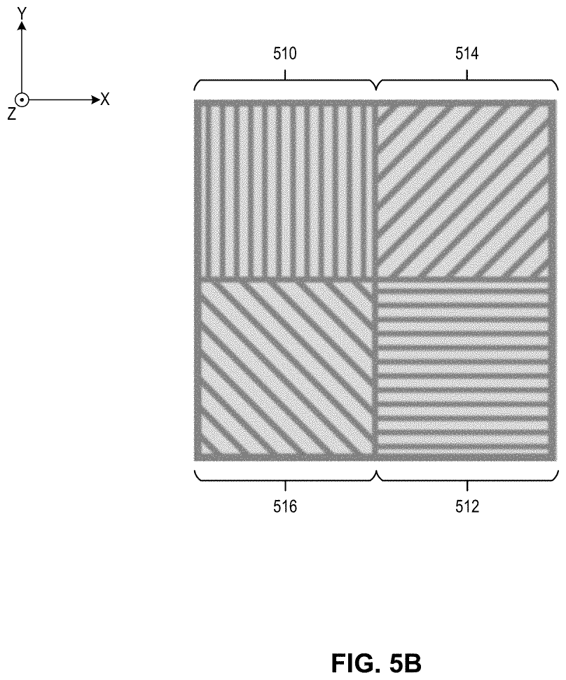

The polarizer can be implemented using various techniques. One example technique is using a wire grid having a pre-determined orientation, which can transmit polarized light components that are orthogonal to the wire grid while reflecting/absorbing polarized light components that are parallel to the wire grid. FIG. 5A illustrates an example of a wire grid polarizer 500, which includes an array of parallel metal strips, such as metal strip 502, aligned along the vertical axis (e.g., Y-axis) forming a wire grid. Wire grid polarizer 500 can transmit horizontal polarized light component 504 of incident light 505 while reflecting/absorbing vertical polarized light component 506. In a case where the array of parallel metal strips of wire grid polarizer 500 are aligned along the horizontal axis (e.g., X-axis), wire grid polarizer 500 can transmit vertical polarized light component 506 while reflecting/absorbing horizontal polarized light component 504. As a result, the orientation of the array of metal strips of wire grid polarizer 500 can control the polarization direction (e.g., a polarization state) of polarized light that can go through the wire grid polarizer.

An image sensor can include multiple wire grid polarizers, each having a different orientation, to separate out light of different polarization directions (e.g., horizontally polarized light, vertically polarized light, and light of 45-degree and 135-degree linear polarization) for intensity measurements. For example, referring to FIG. 5B, an image sensor can include a wire grid polarizer 510 parallel with the X-axis, a wire grid polarizer 512 parallel with the Y-axis, as well as wire grid polarizers 514 and 516 that forms a 45-degree angle with the X-axis or the Y-axis. Wire grid polarizers 510 and 512 can pass, respectively, horizontally polarized light and vertically polarized light, whereas wire grid polarizers 514 and 516 can pass light of 45-degree and 135-degree linear polarization, respectively.

While the wire grid polarizers in FIG. 5A and FIG. 5B can separate out different linear polarized light components by selectively transmitting light of a certain polarization direction, light of other polarization directions are absorbed or reflected by the wire grid polarizers. Such arrangements can reduce the total power of light received by the image sensor and degrade the performance of the image sensor. For example, due to the reduction of the received light power, the signal-to-noise ratio of the image sensor may also reduce. This makes the imaging operation more susceptible to noise, especially in a low ambient light environment.

Another example technique to implement a polarizer is using a birefringent crystal. Birefringence generally refers to the optical property of a material having a refractive index that depends on the polarization and propagation direction of light. Based on the birefringence property, a birefringent crystal can refract orthogonal states of polarized light components by different refraction angles, and project the two light components to different light sensing elements of the image sensor. As the image sensor can still receive the full power of incident light, the signal-to-noise ratio of the image sensor can be maintained.

Equation 7 illustrates a permittivity tensor of a medium, which relates the electric field E and the displacement vector D of light propagating in the medium according to the following Equation:

$$D = [ \begin{matrix}{ɛ}_{11} & {ɛ}_{12} & {ɛ}_{13} \\ {ɛ}_{21} & {ɛ}_{22} & {ɛ}_{23} \\ {ɛ}_{13} & {ɛ}_{32} & {ɛ}_{33}\end{matrix} ] E \qquad ( Equation 7 )$$

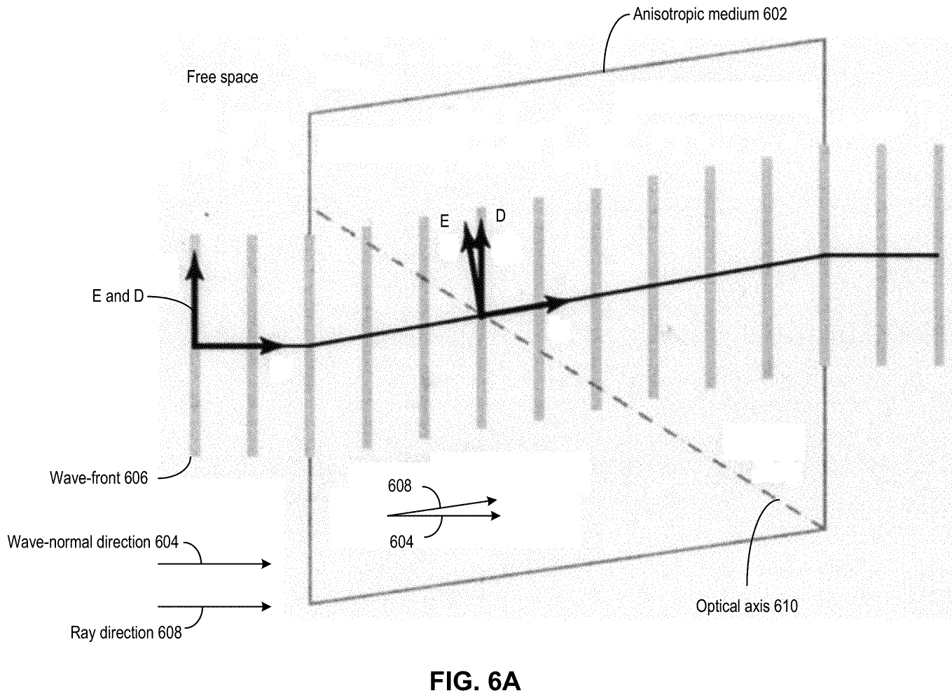

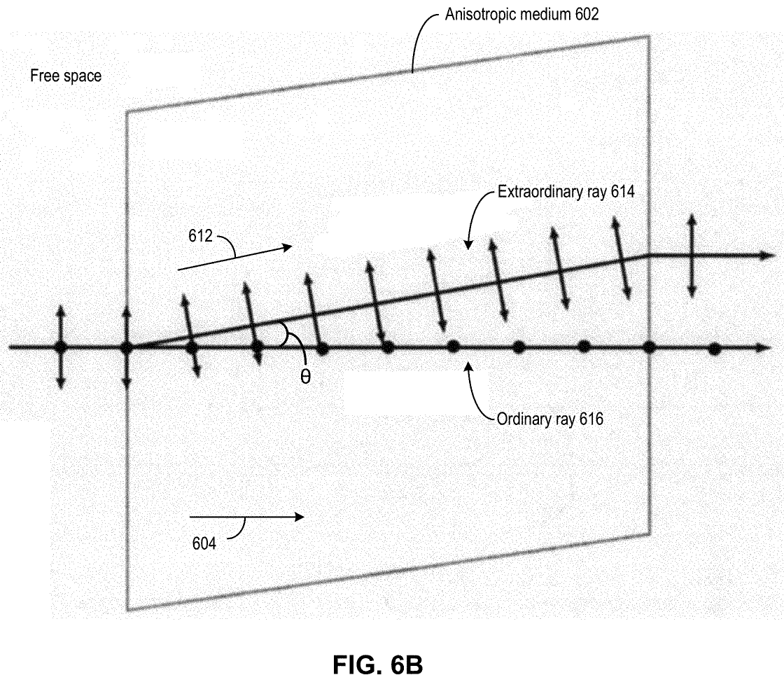

FIG. 6A, and FIG. 6B illustrate two examples of birefringent materials (e.g., birefringent crystals) as polarizers. In a case where the medium is isotropic (e.g., free space), the permittivity of the medium is uniform in all directions. In such a case, permittivity tensor 600 can become a single scaler value ε. In such a case, the direction of the electric field E and the displacement vector D is parallel. But in an anisotropic medium, the permittivity is not uniform and can have different values in different directions, and the permittivity can be represented by permittivity tensor 600.

FIG. 6A illustrates the electric field E and the displacement vector D of the light when light travels between a free space and an anisotropic medium 602. In free space, the direction of the electric field E and the displacement vector D is parallel. As a result, wave-normal direction 604, which is perpendicular to wave-front 606, and ray direction 608, which is the direction of energy flow, are parallel. But when the light travels in anisotropic medium 602, the relationship between the electric field E and the displacement vector D is defined by permittivity tensor 600, and the electric field E is not parallel with the displacement vector D. As a result, wave-normal direction 604 and ray direction 608 in anisotropic medium 602 also become non-parallel. As wave-front 606 moves through anisotropic medium 602, it is continuously displaced in the ray direction 608. The displacement depends on the orientation of an e-vector representing the electric field E with respect to the axes of symmetry of anisotropic medium 602, which can be a crystal.

In some examples, anisotropic medium 602 can include a uni-axial crystal which has one axis, such as optical axis 610, along which D and E are parallel. Examples of uni-axial crystal may include calcite and rutile. Referring to FIG. 6B, as light travels through such a crystal, a first component of light having an electric field that oscillates in a principal plane of the crystal containing optical axis 610 of FIG. 6A can be refracted according to a refractive index nₑ. The first component can travel along a ray direction 612 which is oblique to wave-normal direction 604. The first component of light can be an extraordinary ray 614. A second component of light for which the electric field oscillates perpendicularly to the principal plane can be refracted according to a refractive index nₒ, and the ray direction is parallel with wave-normal direction 604. The second component of light can be an ordinary ray 616.

Referring to FIG. 6B, the ray directions of extraordinary ray 614 and ordinary ray 616 can be separated by an angle θ according to the following Equation:

$$θ = {tan}^{- 1} ( \frac{{n}_{o}^{2}}{{n}_{e}^{2}} tan ( φ ) ) \qquad ( Equation 8 )$$

In Equation 8, nₑ is the refractive index for the extraordinary ray, nₒ is the refractive index for the ordinary ray, whereas φ is the angle between the optical axis (e.g., optical axis 610) and a surface normal of the crystal, which depends on the crystal cut. In order to maximize separation between the ordinary and extraordinary rays, the crystal can be cut so that the optical axis is oriented at 45° to the surface normal.

As the directions of electric fields of extraordinary ray 614 and ordinary ray 616 are perpendicular to each other, extraordinary ray 614 and ordinary ray 616 can be completely orthogonally linearly polarized. The relative intensities of the ordinary and extraordinary rays can reflect the orientation of linear polarization of the incident radiation with respect to the principal plane. For example, if the incident light only includes linearly polarized light having electric fields parallel to a principal plane, all of the incident light can pass through the crystal as extraordinary rays. On the other hand, if the incident light only includes linearly polarized light having electric fields perpendicular to the principal plane, all of the incident light can pass through the crystal as ordinary rays. Therefore, with the property of birefringence, orthogonal linearly polarized light of different polarization directions can be separated out and projected to different light sensing elements of the image sensor to the composition of an incident ray in terms of orthogonal linearly polarized components.

### An Example Image Sensor

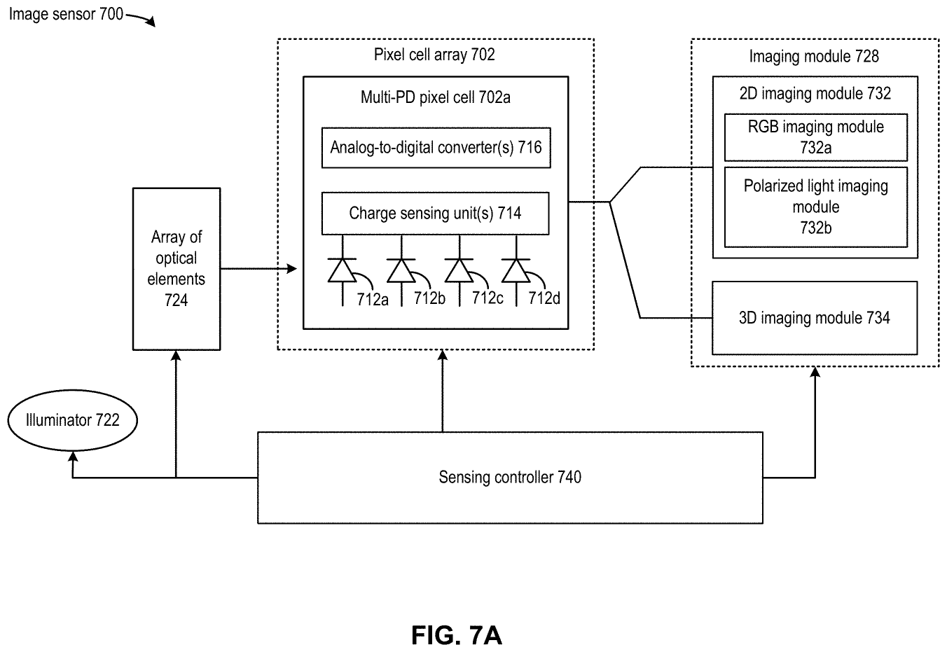

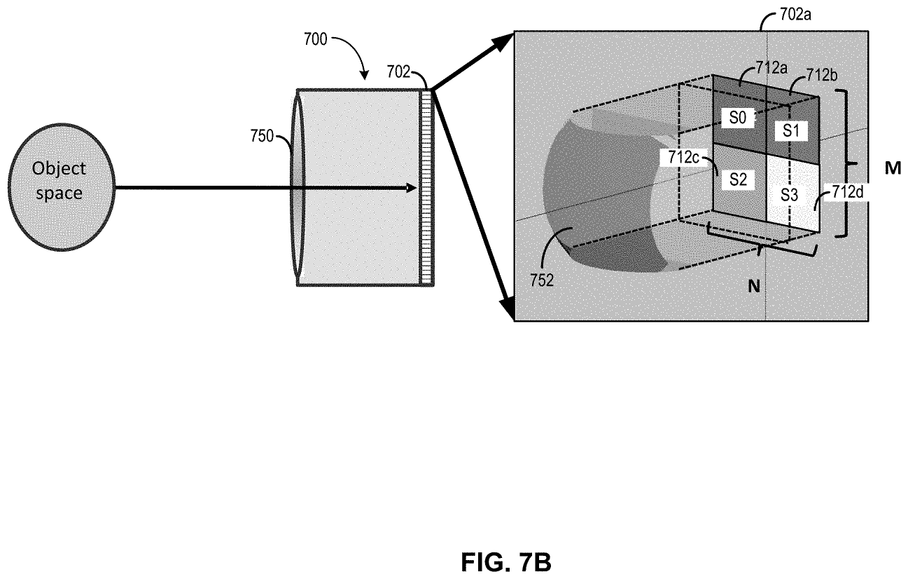

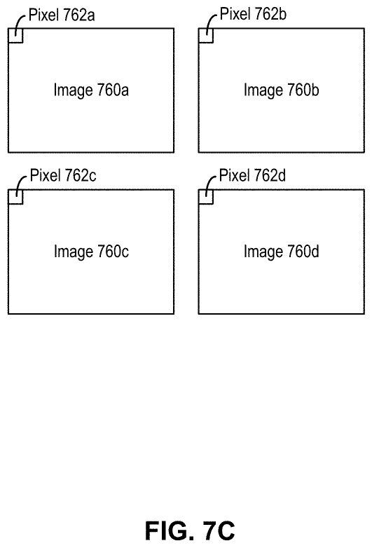

FIG. 7A illustrates an embodiment of a sensor controller layout for an image sensor 700 that can perform measurements of polarized light as well as light having other properties. As shown in FIG. 7, image sensor 700 may include an array of pixel cells 702 including pixel cell 702a. Although FIG. 7 illustrates only a single pixel cell 702, it is understood that an actual pixel cell array 702 can include many pixel cells.

Pixel cell 702a can include a plurality of photodiodes 712 including, for example, photodiodes 712a, 712b, 712c, and 712d, one or more charge sensing units 714, and one or more analog-to-digital converters 716. The plurality of photodiodes 712 can convert different components of incident light to charge. The components can include, for example, orthogonal linearly polarized light of different polarization directions, light components of different frequency ranges, etc. For example, photodiodes 712a-712d can detect the intensities of, respectively, linearly polarized light having electric fields parallel to a principal plane, linearly polarized light having electric fields perpendicular to the principal plane, and polarized light having electric fields that form 45 degrees from the principal plane. As another example, photodiodes 712a and 712b can detect the intensities of two orthogonal linearly polarized light of two different polarization directions, photodiode 712c can detect the intensity of unpolarized visible light, whereas photodiode 712d can detect the intensity of infrared light. Each of the one or more charge sensing units 714 can include a charge storage device and a buffer to convert the charge generated by photodiodes 712a-712d to voltages, which can be quantized by one or more ADCs 716 into digital values. Although FIG. 7A shows that pixel cell 702a includes four photodiodes, it is understood that the pixel cell can include a different number of photodiodes (e.g., two, three, etc.).

In some examples, image sensor 700 may also include an illuminator 722, an array of optical elements 724, an imaging module 728, and a sensing controller 740. Illuminator 722 may be a near infrared illuminator, such as a laser, a light emitting diode (LED), etc., that can project near infrared light for 3D sensing. The projected light may include, for example, structured light, polarized light, light pulses, etc. Array of optical elements 724 can include an optical element overlaid on the plurality of photodiodes 712a-712d of each pixel cell including pixel cell 702a. The optical element can select the polarization/wavelength property of the light received by each of photodiodes 712a-712d in a pixel cell.

In addition, image sensor 700 further includes an imaging module 728. Imaging module 728 may further include a 2D imaging module 732 to perform 2D imaging operations and a 3D imaging module 734 to perform 3D imaging operations. 2D imaging module 732 may further include an RGB imaging module 732a and a polarized light imaging module 732b. The operations can be based on digital values provided by ADCs 616. In one example, based on the digital values from each of photodiodes 712a-712d, polarized light imaging module 732b can obtain polarimetric information, such as intensity values I_{H}, I_{V}, L₊₄₅ and I₋₄₅, to determine Stoke parameters S₁ and S₂, and then generate DOP and/or AOP pixel values based on Equations 4 and 5. In another example, RGB imaging module 732a can also determine intensity values of visible incident light (which can contain polarized and unpolarized light) from photodiode 712c from each pixel cell, and generate an RGB pixel value for that pixel. Moreover, 3D imaging module 734 can generate a 3D image based on the digital values from photodiode 712d. Image sensor 700 further includes a sensing controller 740 to control different components of image sensor 700 to perform 2D and 3D imaging of an object.

FIG. 7B illustrates a sensor optics layout for image sensor 700. As shown in FIG. 7B, image sensor 700 further includes a camera lens 750 and a two-dimensional pixel cell array 702, including pixel cell 702a. Pixel cell 702a can be configured as a super-pixel. Here, each “super-pixel” refers to a sensor device that may comprise an N×M array of neighboring (i.e., adjacent) sub-pixels, each sub-pixel having a photodiode for converting energy of light of a particular wavelength into a signal. In FIG. 7B, sub-pixels S0, S1, S2, and S3 including, respectively, photodiodes 712a, 712b, 712c, and 712d of FIG. 7A are shown.

A shared optical element, such as a microlens 752 which can be part of array of optical elements 724, may be positioned between the scene and photodiodes 712a, 712b, 712c, and 712d. In some examples, each super-pixel may have its own microlens. Microlens 752 may be significantly smaller in size than camera lens 706, which serves to accumulate and direct light for the entire image frame toward pixel cell array 702. Microlens 752 is a “shared” optical element, in the sense that it is shared among photodiodes 712a, 712b, 712c, and 712d. Microlens 752 directs light from a particular location in the scene to photodiodes 712a-712d. In this manner, the sub-pixels of a super-pixel can simultaneously sample light from the same spot of a scene, and each sub-pixel can generate a corresponding pixel value in an image frame. In some examples, microlens 752 can be positioned over and shared by multiple pixels as well. On pixel cell array 702, there can be an array of microlenses 752, which are between the camera lens 750 and photodiodes of the pixel cell array 702

FIG. 7C depicts a relationship between four image frames generated from the image sensor 700 during one exposure period, according to some embodiments. During one exposure period, image frames 760a, 760b, 760c, and 760d are generated by light detected by the pixel cell array 702. Light detected by pixel cell 702a in FIG. 7B is used in pixels 762a, 762b, 762c, and 762d. For example, light detected by photodiode 712a is used for pixel 762a; light detected by photodiode 712b is used for pixel 762b; light detected by photodiode 712c is used for pixel cell 762c; and light detected by photodiode 712d is used for pixel 762d. Pixels 762a, 762b, 762c, and 762d have the same relative location in image frames 760a-760d. Thus, N×M image frames 760 can be generated from each exposure of the pixel cell array 702, since there are N×M photodiodes per super pixel cell of the pixel cell array 702.

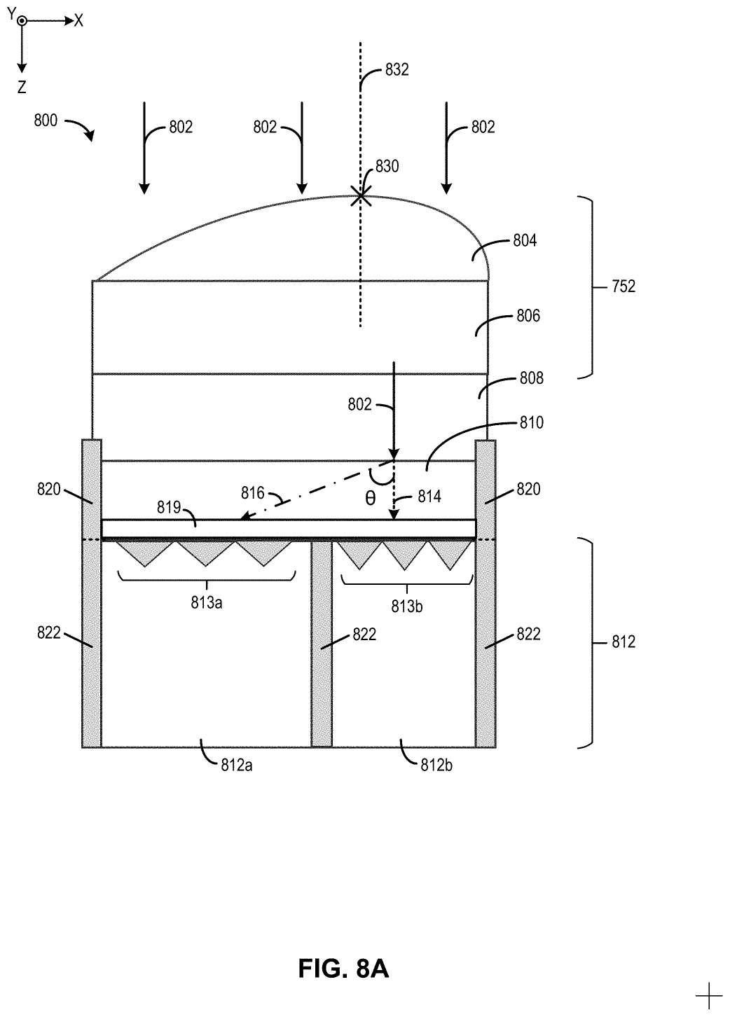

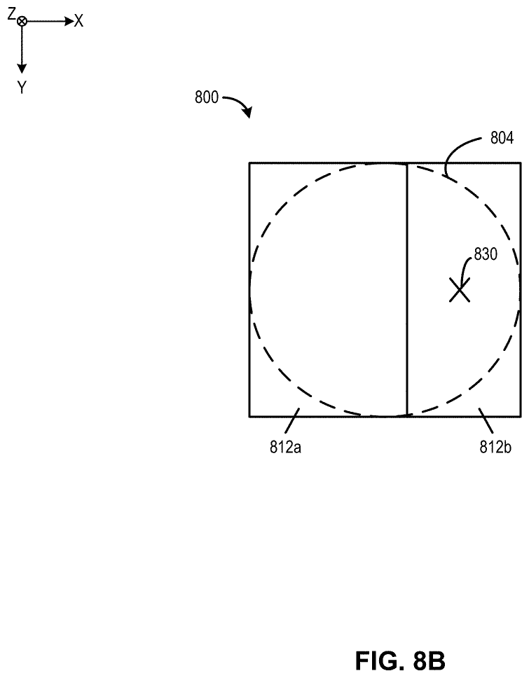

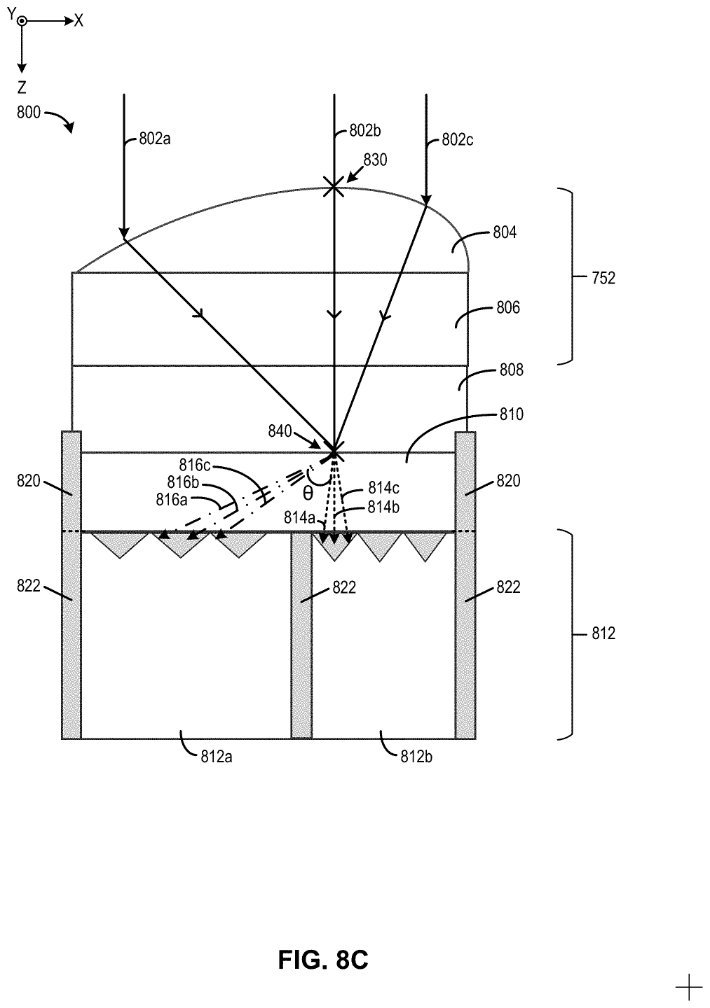

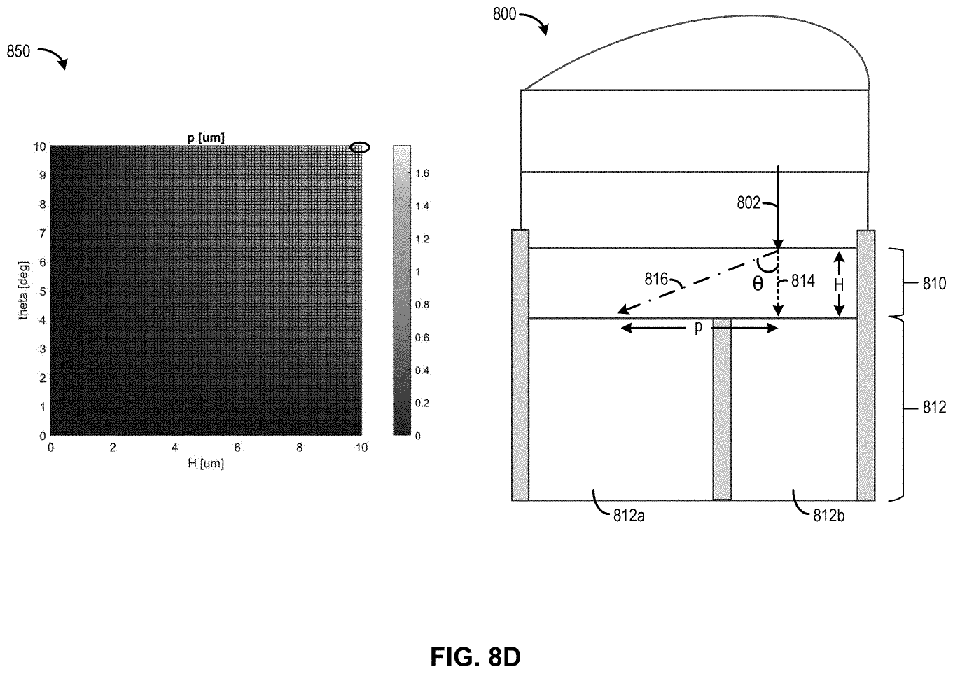

FIG. 8A-FIG. 8D present additional components of an embodiment of a pixel cell, such as pixel cell 702a in FIG. 7B. FIG. 8A is a side view of an embodiment of a pixel cell. FIG. 8B is a top view of an embodiment of a pixel cell. FIG. 8C is a side view of an embodiment of a pixel cell focusing light using a microlens. FIG. 8D is a side view of an embodiment of a pixel cell showing how depth of a birefringent crystal affects lateral separation of optical components of incident light.

As shown in FIG. 8A, the pixel cell can be implemented as a multi-layer semiconductor sensor device 800. In the orientation shown in FIG. 8A, received light 802 travels from the top of the pixel cell, through microlens 752 and various layers along the Z-axis, to reach a plurality of sub-pixels located at the bottom of the sensor device. Multi-layer semiconductor sensor device 800 comprises multiple layers including microlens 752 including a microlens top layer 804, a microlens under layer 806, an oxide layer 808, a birefringent crystal 810, a sub-pixel layer 812 including sub-pixels 812a and 812b. In some examples, sub-pixel layer 812 may include one or more silicon-based insulation structures, such as deep trench isolations (DTI) 822. Microlens under layer 806 can be optional. In some examples, sensor device 800 may include filter (not shown in the figures) between microlens under layer 806 and birefringent crystal 810 to select light of different wavelengths to enter sub-pixels 812a and 812b. Optionally, sensor device 800 may include a layer of absorption structure 813 (e.g., 813a and 813b) to enhance the light collection efficiency of sub-pixels 812a and 812b. Absorption structure 813 can include, for example, inverted pyramid structures. Together with DTI 822, absorption structure 813 can trap light energy within sub-pixels 812a and 812b by total internal reflection to increase effective light travel distance within the silicon and to enhance light absorption by sub-pixels 812a and 812b.

Birefringent crystal 810 can separate out orthogonal linearly polarized light components of different polarization directions in light 802, and project the different polarized light components to sub-pixels 812a and 812b. Specifically, as light 802 enters birefringent crystal 810, an ordinary ray component 814 of light 802 can be refracted by birefringent crystal 810 according to the refractive index nₒ, whereas an extraordinary ray component 816 of light 802 can be refracted by birefringent crystal 810 according to the refractive index nₑ. As a result, the propagation directions of the two ray components can be separated by an angle θ based on Equation 8 above. Ordinary ray component 814 can propagate to and be measured by sub-pixel 812b, whereas extraordinary ray component 816 can propagate to and be measured by sub-pixel 812a. With such arrangements, sub-pixel 812a and sub-pixel 812b can measure the intensities of orthogonally linearly polarized lights to provide measurements of intensities I_{H} and I_{V}.

In some examples, pixel cell 702a may include a wave plate 819 sandwiched between birefringent crystal 810 and sub-pixel layer 812. Wave plate 819 can act as a half-wave retarder which can rotate a state of linear polarization from one of the ray components 814 or 816, which can be measured by sub-pixels 812a and 812b to provide measurements of new intensities at the new linear polarization states.

In addition, pixel cell 702a may include insulation structures to reduce cross-talks. For example, birefringent crystal 810 may include one or more metallic-based insulation structures, such as a backside metallization (BSM) structure 820, to prevent light from propagating to another birefringent crystal 810 of a neighboring pixel cell to reduce the cross-talks between pixel cells. The BSM structure may include an absorptive metal material to avoid un-desired reflections. In addition, deep trench isolations (DTI) 822 can prevent different polarized light components 814 and 816 from propagating between sub-pixels 812a and 812b to reduce the cross-talks between sub-pixels. DTI 822, together with absorption structure 813, can also cause total internal reflection of the incident light to increase effective light travel distance within the silicon and to enhance light absorption by sub-pixels 812a and 812b. In some examples, an anti-reflection coating can be applied to the DTI to reduce un-desired light reflections.

In some examples, to further reduce the cross-talks between sub-pixels, microlens top layer 804 can be shaped to facilitate the propagation of different polarized light components to their target sub-pixels. FIG. 8A and FIG. 8B illustrates additional details of microlens top layer 804. FIG. 8B illustrates a top view of semiconductor sensor device 800 including sub-pixels 812a and 812b. Referring to FIG. 8A and FIG. 8B, microlens top layer 804 can have an asymmetric curvature, such that the apex point 830 of the curvature of microlens top layer 804, which is normal to optical axis 832 at apex point 830, overlays on sub-pixel 812b.

The asymmetric curvature of microlens top layer 804 can guide/focus light 802 towards a point 840 directly below apex point 830 and above sub-pixel 812b. Such arrangements can focus ordinary ray component 814 and extraordinary ray component 816 to the intended sub-pixels (sub-pixels 812b and 812a respectively), while diverting these ray components away from the unintended sub-pixels. FIG. 8C illustrates the propagation of light 802 and its polarized light components within semiconductor sensor device 800. As shown in FIG. 8C, microlens top layer 804 can guide lights 802a, 802b, and 802c to enter birefringent crystal 810 at point 840. Light 802b can be normal to the curvature of microlens top layer 804 and enter microlens top layer 804 at apex point 830. As a result, light 802b is not refracted and travels straight after exiting microlens top layer 804. Light 802b is also incident upon birefringent crystal 810 at a normal angle of incidence, and birefringent crystal 810 can separate ordinary ray component 814b from extraordinary ray component 816a of light 802b. Ordinary ray component 814b of light 802b can also pass straight through birefringent crystal 810 and enter sub-pixel 812b as intended, instead of propagating to sub-pixel 812a. Meanwhile, extraordinary ray component 816b can propagate at a direction that forms angle θ, based on Equation 8 above, from ordinary ray component 814b and towards sub-pixel 812a instead of sub-pixel 812b. In addition, lights 802a and 802c are incident upon birefringent crystal 810 at different angles, and ordinary ray components 814a and 814c of these lights can be refracted by birefringent crystal 810 towards sub-pixel 812b (as intended) based on refractive index nₒ and according to Snell's law, instead of propagating to sub-pixel 812a. Extraordinary ray components 816a and 816c of lights 802a and 802c also propagate towards sub-pixel 812a at angle θ from, respectively, ordinary ray components 814a and 814c.

Referring to FIG. 8D, the depth of birefringent crystal 810 (represented by H) can be based on a desired lateral separation distance (also known as walk-off distance) p between the entry points of ordinary ray component 814 and extraordinary ray component 816 at, respectively, sub-pixels 812b and 812a. Specifically, walk-off distance p, the depth H of birefringent crystal 810, and the refraction angle θ can be related based on the following Equation:

p=H tan(θ) (Equation 9)

The walk-off distance p can be determined based on, for example, the pitch of a sub-pixel, separation between two center points of sub-pixels, etc. The refraction angle θ can be determined based on Equation 8 (reproduced below) as well as nₑ (the refractive index for the extraordinary ray), nₒ (the refractive index for the ordinary ray), and φ (between the optical axis and a surface normal of the crystal).

$$θ = {tan}^{- 1} ( \frac{{n}_{o}^{2}}{{n}_{e}^{2}} tan ( φ ) ) \qquad ( Equation 8 )$$

The refractive indices nₒ and nₑ can be determined based on the wavelength of light 802 according to the Sellmeier Equation, as follows:

nₒ²=2.69705+0.0192064/(λ²−0.01820)−0.0151624λ² (Equation 10)

nₑ²=2.18438+0.0087309/(λ²−0.01018)−0.00244112 (Equation 11)

The following table describes different refractive indices nₒ and nₑ for different wavelengths:

TABLE 1

| Wavelength | nₒ | nₑ | Δn = nₑ − nₒ | Refraction angle θ |
|---|---|---|---|---|
| 0.63 um | 1.6557 | 1.4852 | −0.1705 | 6.20° |
| 1.30 um | 1.6629 | 1.4885 | −0.1744 | 6.32° |

Graph 850 illustrates a distribution of walk-off distance p (between 0-1.8 um) for different combinations of depth (H) and refraction angle (theta θ). For example, a walk-off distance p of 1.8 um can be achieved with a depth H of 10 um and a refraction angle θ of 10°.

The multiple layers of device 800 and devices fabricated therein are built on a common semiconductor die using one or more semiconductor processing techniques such as lithography, etching, deposition, chemical mechanical planarization, oxidation, ion implantation, diffusion, etc. (e.g., photodiodes are formed in a semiconductor substrate). This is in contrast to building the layers as separate components, then aligning and assembling the components together in a stack. Such alignment and assembly may cause significant precision and manufacturing defect issues, especially as the physical dimensions of the sensor device is reduced to the scale of single-digit micrometers. The design of the super-pixel as a multi-layer semiconductor sensor device 800 allows components such as sub-pixels, wavelength filters, the birefringent crystal, and the microlens to be precisely aligned, as controlled by semiconductor fabrication techniques, and avoids issues of misalignment and imprecision that may be associated with micro assembly.

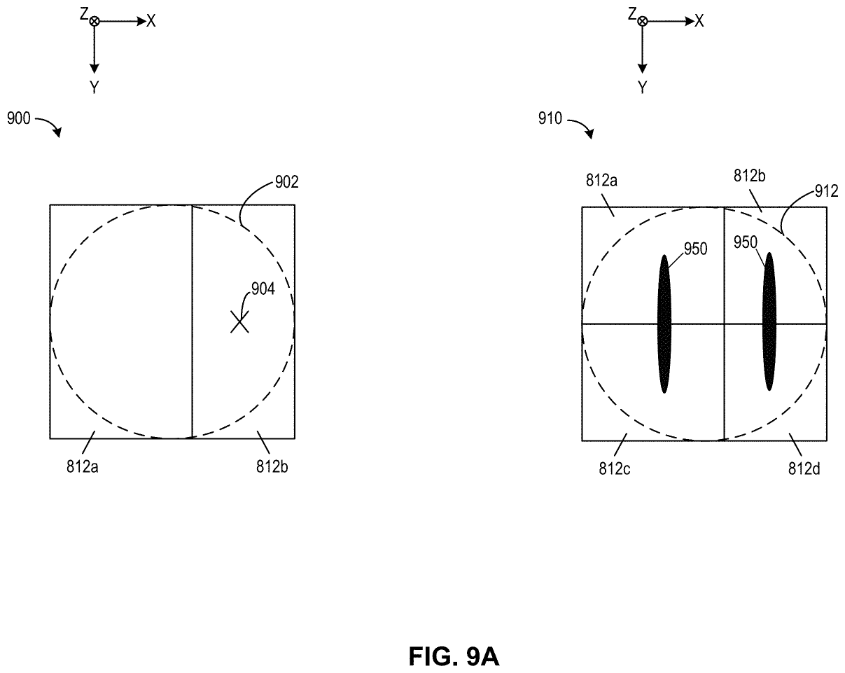

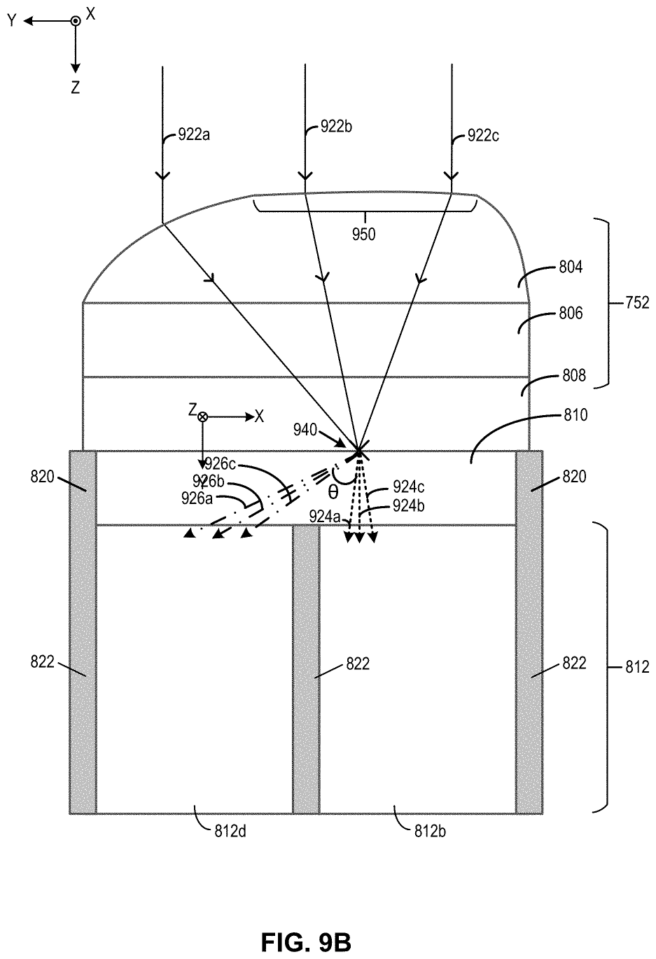

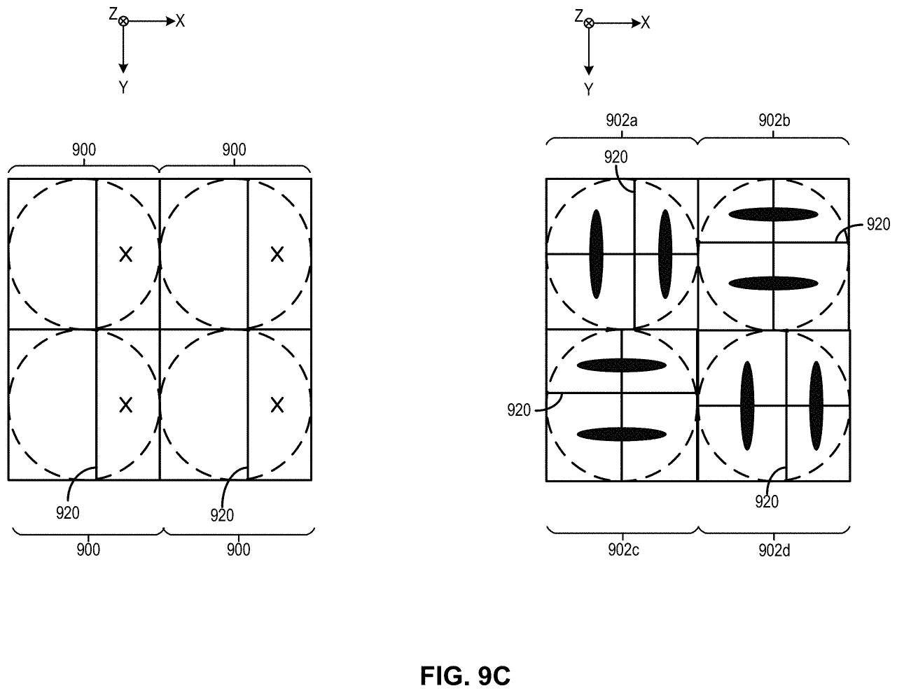

FIG. 9A, FIG. 9B, and FIG. 9C, illustrate additional examples of pixel cells, according to some embodiments. FIG. 9A illustrates top view of embodiments of pixel cells showing locations of an apex and flat portions of microlenses. FIG. 9B is a side view of an embodiment of a pixel cell with a microlens having one or more flat portions.

In FIG. 9A, pixel cell 900 can include two sub-pixels 812a and 812b, and microlens 902 can have an asymmetric curvature along the X-axis, and an apex point 904 over sub-pixel 812b, to guide light to enter birefringent crystal 810 at a point directly over sub-pixel 812b as shown in FIG. 8C.

In addition, pixel cell 910 can include four sub-pixels 812a, 812b, 812c, and 812d.

Microlens 912 over pixel cell 910 can also have an asymmetric curvature. In such example, microlens 912 can have an asymmetric curvature along the Y-axis as well. FIG. 9B illustrates a cross-sectional view of pixel cell 910 viewing from the Y-axis, where sub-pixel 812d is adjacent to sub-pixel 812b. As shown in FIG. 9B, with the asymmetric curvature, microlens top layer 804 can guide lights 922a, 922b, and 922c to enter birefringent crystal 810 at a point 940 above sub-pixel 812b (e.g., over a center of sub-pixel 812b) rather than above DTI 822 that separates between sub-pixels 812b and 812d. As in FIG. 8C, this allows extraordinary components 926a, 926b, and 926c of, respectively, lights 922a, 922b, and 922c to enter sub-pixel 812d, whereas ordinary ray components 924a, 924b, and 924c of, respectively, lights 922a, 922b, and 922c can enter sub-pixel 812b. In some examples, microlens top layer 804 can have a cylindrical shape having a flat portion 950 that has a reduced curvature compared with other parts of the top layer. As in FIG. 8C, pixel cell 910 can have DTI structures 822 between sub-pixels 812b and 812d between sub-pixels, and between pixels, to reduce cross-talk.

FIG. 9C illustrates example arrays of pixel cells 900 and 902. For example, each pixel cell in array of pixel cells 900 can have the same orientation of principle plane 920 (e.g., being parallel with the Y-axis) such that sub-pixel 812b of each pixel cell 900 can measure ordinary ray component having E-field perpendicular to principal plane 920/Y-axis and sub-pixel 812a of each pixel cell 900 can measure extraordinary ray component having E-field parallel with principal plane 920. As another example, in array of pixel cells 902, pixel cells 902 can have different orientations of principal plane 920. For example, principal plane 920 of pixel cells 902a and 902d can be aligned with the Y-axis, whereas principal plane 920 of pixel cells 902b and 902c can be aligned with the X-axis. As a result, sub-pixels 812b and 812d of pixel cells 902a and 902d can measure ordinary ray component having E-field perpendicular to Y-axis, whereas sub-pixels 812b and 812d of pixel cells 902b and 902c can measure extraordinary ray component having E-field perpendicular to X-axis (and parallel with the Y-axis).

Although not shown in FIG. 9A and FIG. 9B, it is understood that pixel sizes can be varied across the pixel cell array for best modulation transfer function (MTF)/resolution for on-axis and off-axis cases. Moreover, in some examples some of the pixel cells may include a color filter for both polarization and color visions.

### Device Context and Hardware

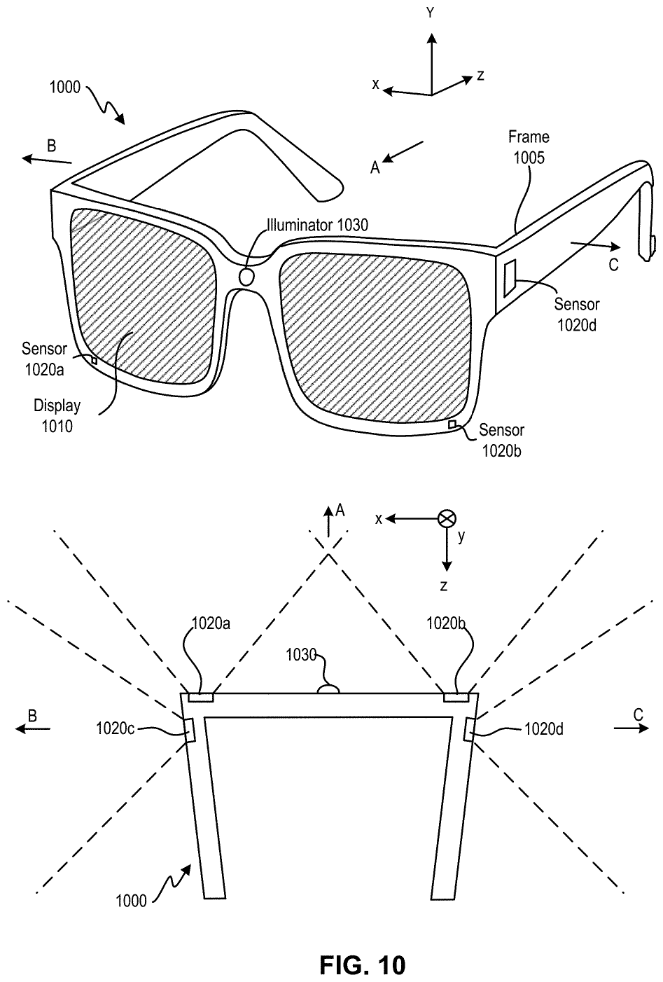

FIG. 10 presents a mobile device 1000 in which one or more polarimetric sensor arrays described in the present disclosure, such as those comprising unit cells made up of superpixels and sub-pixels, may be deployed. In some examples, mobile device 1000 can be in the form of a head mounted display (HMD). An HMD is merely one illustrative use case. A polarimetric sensor array of the present disclosure can be used in a wide variety of other contexts. A primary purpose served by HMD 1000 may be to present media to a user. Examples of media presented by HMD 1000 include one or more images, video, and/or audio. In some examples, audio is presented via an external device (e.g., speakers and/or headphones) that receives audio information from the HMD 1000, a console, or both, and presents audio data based on the audio information. HMD 1000 is generally configured to operate as a virtual reality (VR) display. In some examples, HMD 1000 is modified to operate as an augmented reality (AR) display and/or a mixed reality (MR) display.

HMD 1000 includes a frame 1005 and a display 1010. Frame 1005 is coupled to one or more optical elements. Display 1010 is configured for the user to see content presented by HMD 1000. In some examples, display 1010 comprises a waveguide display assembly for directing light from one or more images to an eye of the user.

HMD 1300 further includes image sensors 1020a, 1020b, 1020c, and 1020d. Each of image sensors 1020a, 1020b, 1020c, and 1020d may include a pixel cell array configured to generate image data representing different fields of views along different directions. Such an image cell array may incorporate a polarimetric sensor array described in the present disclosure. For example, sensors 1020a and 1020b may be configured to provide image data representing two fields of view towards a direction A along the Z axis, whereas sensor 1020c may be configured to provide image data representing a field of view towards a direction B along the X axis, and sensor 1020d may be configured to provide image data representing a field of view towards a direction C along the X axis.

In some examples, HMD 1000 may further include one or more active illuminators 1030 to project light into the physical environment. The light projected can be associated with different frequency spectrums (e.g., visible light, infrared light, ultra-violet light, etc.), and can serve various purposes. For example, illuminator 1030 may project light in a dark environment (or in an environment with low intensity of infrared light, ultra-violet light, etc.) to assist sensors 1020a-1020d in capturing images of different objects within the dark environment to, for example, enable location tracking of the user. Illuminator 1030 may project certain markers onto the objects within the environment, to assist the location tracking system in identifying the objects for map construction/updating.

HMD 1000 may include sensors (e.g., sensors similar to sensors 1020) that are inward facing (e.g., sensors for eye/pupil tracking of the user).

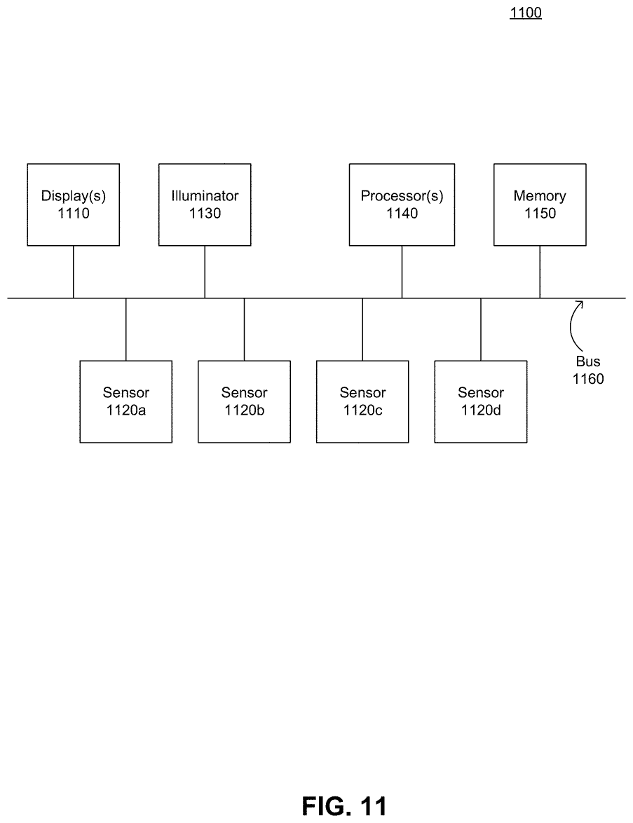

FIG. 11 presents a block diagram showing an internal view of some of the main components of HMD 1000. As shown, HMD 1000 may comprise components such as one or more displays 1110, sensors 1120a-1120d, illuminator 1130, processor(s) 1140, and memory 1150. These components may be interconnected using one or more networking or bus systems 1160. Processor(s) 1140 may carry out programmed instructions and support a wide variety of computational tasks on behalf of other components such as display(s) 1110 an sensors 1120a-1120d. While shown as a single block in FIG. 11, processor(s) 1140 may be distributed in different locations and within different components. For example, processor(s) 1140 may carry out computations on behalf of a polarimetric sensor array to estimate a Stokes vector. As another example, processor(s) 1140 may compute values such as DOP and AOP based on the estimated Stokes vector. Memory 1150 may constitute different types of memory, e.g., RAM, ROM, internal memory, etc., to provide volatile or non-volatile storage of data in support of operations of processor(s) 1140 and other components of HMID 1000.

### Example Process

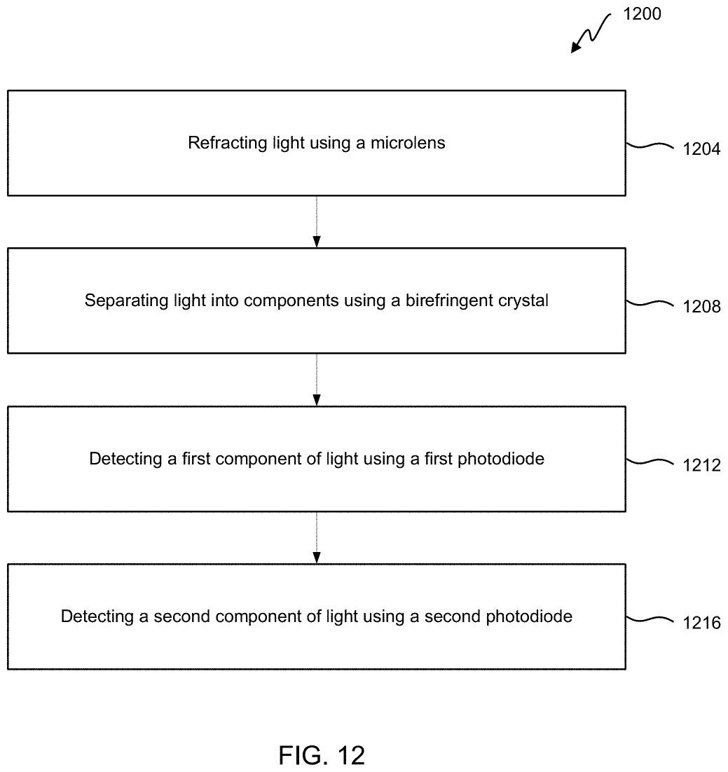

FIG. 12 illustrates a flowchart of an embodiment of a process 1200 for detecting polarized light. The process 1200 begins in step 1204 with refracting light using a microlens to produce refracted light. For example, the microlens 752 in FIG. 8A is used to focus light onto a birefringent crystal 810 and/or the sub-pixel layer 812. A first photodiode (e.g., sub-pixel 812b) is positioned adjacent to a second photodiode (e.g., sub-pixel 812a) is a semiconductor substrate (e.g., sub-pixel layer 812) along a first axis (e.g., the x-axis in FIG. 8A). The microlens is positioned over the birefringent crystal along a second axis (e.g., the microlens 752 is positioned over the birefringent crystal 810 along the z-axis in FIG. 8A). The second axis is orthogonal to the first axis. The microlens has an asymmetric curvature along the first axis and an apex point of the asymmetric curvature is positioned over the first photodiode along the second axis (e.g., the apex point 830 is over the sub pixel 812b along the z-axis in FIG. 8A).

In step 1208, refracted light from the microlens is separated into a first component of light and a second component of light, using the birefringent crystal. For example, the ordinary ray component 814 of light 802 is separated from the extraordinary ray component 816 of light 802 in FIG. 8A. The birefringent crystal is positioned over the first photodiode and the second photodiode along the second axis. For example, the birefringent crystal 810 is positioned over sub pixels 812a and 812b along the z-axis.

In step 1212, the first component of light is detected using the first photodiode. For example, sub pixel 812b measures the ordinary ray component 814 of light 802 in FIG. 8A.

In step 1216, the second component of light is detected using the second photodiode. For example, sub pixel 812a measures the extraordinary ray component 816 of light 802 in FIG. 8A.

In some embodiments, the first component of light is a first linear polarization and the second component of light is a second linear polarization, wherein the second linear polarization is orthogonal to the first linear polarization; the microlens is part of an optical element, and the method further comprises generating image frames using an array of optical elements (e.g., as described in conjunction with FIGS. 7A-7C); separating light into components comprises refracting an ordinary ray component of the incident light by a first angle, the first angle being based on a first refractive index associated with the ordinary ray component, the ordinary ray component having a first electric field that is perpendicular to a principal plane of the birefringent crystal, and refracting an extraordinary ray component of the incident light by a second angle, the second angle being based on a second refractive index associated with the extraordinary ray component, the extraordinary ray component having a second electric field that is parallel with the principal plane of the birefringent crystal; focusing incident light to an entry point on the birefringent crystal over the first photodiode along the second axis; rotating polarization using a wave plate between the birefringent crystal and the semiconductor substrate; and/or filtering a color of light using a filter between the microlens and the semiconductor substrate along the second axis.

The disclosed techniques may include or be implemented in conjunction with an artificial reality system. Artificial reality is a form of reality that has been adjusted in some manner before presentation to a user, which may include, e.g., a virtual reality (VR), an augmented reality (AR), a mixed reality (MR), a hybrid reality, or some combination and/or derivatives thereof. Artificial reality content may include completely generated content or generated content combined with captured (e.g., real-world) content. The artificial reality content may include video, audio, haptic feedback, or some combination thereof, any of which may be presented in a single channel or in multiple channels (such as stereo video that produces a three-dimensional effect to the viewer). Additionally, in some examples, artificial reality may also be associated with applications, products, accessories, services, or some combination thereof, that are used to, e.g., create content in an artificial reality and/or are otherwise used in (e.g., perform activities in) an artificial reality. The artificial reality system that provides the artificial reality content may be implemented on various platforms, including a head-mounted display (HMD) connected to a host computer system, a standalone HMD, a mobile device or computing system, or any other hardware platform capable of providing artificial reality content to one or more viewers.

Some portions of this description describe the examples of the disclosure in terms of algorithms and symbolic representations of operations on information. These algorithmic descriptions and representations are commonly used by those skilled in the data processing arts to convey the substance of their work effectively to others skilled in the art. These operations, while described functionally, computationally, or logically, are understood to be implemented by computer programs or equivalent electrical circuits, microcode, or the like. Furthermore, it has also proven convenient at times, to refer to these arrangements of operations as modules, without loss of generality. The described operations and their associated modules may be embodied in software, firmware, and/or hardware.

Steps, operations, or processes described may be performed or implemented with one or more hardware or software modules, alone or in combination with other devices. In some examples, a software module is implemented with a computer program product comprising a computer-readable medium containing computer program code, which can be executed by a computer processor for performing any or all of the steps, operations, or processes described.

Examples of the disclosure may also relate to an apparatus for performing the operations described. The apparatus may be specially constructed for the required purposes, and/or it may comprise a general-purpose computing device selectively activated or reconfigured by a computer program stored in the computer. Such a computer program may be stored in a non-transitory, tangible computer readable storage medium, or any type of media suitable for storing electronic instructions, which may be coupled to a computer system bus. Furthermore, any computing systems referred to in the specification may include a single processor or may be architectures employing multiple processor designs for increased computing capability.

Examples of the disclosure may also relate to a product that is produced by a computing process described herein. Such a product may comprise information resulting from a computing process, where the information is stored on a non-transitory, tangible computer readable storage medium and may include any example of a computer program product or other data combination described herein.

The language used in the specification has been principally selected for readability and instructional purposes, and it may not have been selected to delineate or circumscribe the inventive subject matter. It is therefore intended that the scope of the disclosure be limited not by this detailed description, but rather by any claims that issue on an application based hereon. Accordingly, the disclosure of the examples is intended to be illustrative, but not limiting, of the scope of the disclosure, which is set forth in the following claims.

What is claimed is:

1. An apparatus, comprising:
a semiconductor substrate comprising a first photodiode and a second photodiode, the first photodiode being positioned adjacent to the second photodiode along a first axis;
a birefringent crystal positioned over the first photodiode and the second photodiode along a second axis perpendicular to the first axis; and
a microlens positioned over the birefringent crystal along the second axis, the microlens having an asymmetric curvature along the first axis, an apex point of the asymmetric curvature being positioned over the first photodiode along the second axis.

2. The apparatus of claim 1, wherein the microlens is configured to focus incident light on the birefringent crystal over the first photodiode along the second axis.

3. The apparatus of claim 2, further comprising a wave plate sandwiched between the birefringent crystal and the semiconductor substrate, the wave plate being configured to rotate a polarization state of the incident light.

4. The apparatus of claim 2, wherein:
the birefringent crystal is configured to:
refract an ordinary ray component of the incident light by a first angle, the first angle being based on a first refractive index associated with the ordinary ray component, the ordinary ray component having a first electric field that is perpendicular to a principal plane of the birefringent crystal; and
refract an extraordinary ray component of the incident light by a second angle, the second angle being based on a second refractive index associated with the extraordinary ray component, the extraordinary ray component having a second electric field that is parallel with the principal plane of the birefringent crystal;
the first photodiode is configured to measure an intensity of the ordinary ray component; and
the second photodiode is configured to measure an intensity of the extraordinary ray component.

5. The apparatus of claim 4, wherein the second angle is related to the first angle based on the first refractive index, the second refractive index, and a third angle between an optical axis of the birefringent crystal and a surface normal of the birefringent crystal.

6. The apparatus of claim 4, wherein a depth of the birefringent crystal is based on: (i) a separation between a center of the first photodiode and a center of second photodiode and (ii) a wavelength of light of the extraordinary ray component and the ordinary ray component.

7. The apparatus of claim 1, wherein:
the semiconductor substrate comprises a deep trench isolation (DTI) formed between the first photodiode and the second photodiode along the first axis;
the first photodiode and the second photodiode are part of a pixel cell array comprising pixel cells;
each pixel cell comprises a plurality of photodiodes; and
the semiconductor substrate comprises DTI formed between the pixel cells of the pixel cell array.

8. The apparatus of claim 1, further comprising a layer of light absorption structure sandwiched between the birefringent crystal and the semiconductor substrate, the layer of light absorption structure being configured to enhance a light collection efficiency of each of the first photodiode and the second photodiode.

9. The apparatus of claim 1, further comprising a color filter sandwiched between the microlens and the semiconductor substrate along the second axis.

10. The apparatus of claim 1, wherein:
the first photodiode and the second photodiode are part of, respectively, a first sub-pixel and a second sub-pixel;
the apparatus is configured to:
generate a first pixel of a first image frame based on a first output of the first photodiode; and
generate a second pixel of a second image frame based on a second output of the second photodiode; and
the first pixel corresponds to the second pixel.

11. An apparatus comprising an array of pixel cells, each pixel cell comprising:
a first photodiode and a second photodiode formed in a semiconductor substrate, the first photodiode being positioned adjacent to the second photodiode along a first axis;
a birefringent crystal positioned over the first photodiode and the second photodiode along a second axis perpendicular to the first axis; and
a microlens positioned over the birefringent crystal along the second axis, the microlens having an asymmetric curvature, an apex point of the asymmetric curvature being positioned over the first photodiode along the second axis.

12. The apparatus of claim 11, wherein the asymmetric curvature is a first asymmetric curvature, wherein:
each pixel cell, of the array of pixel cells, further comprises a third photodiode and a fourth photodiode;
the first photodiode, the second photodiode, the third photodiode, and the fourth photodiode forms a two-by-two array of photodiodes;
the microlens is positioned over the two-by-two array of photodiodes along the second axis; and
the microlens has a second asymmetric curvature along a third axis along which the first photodiode is positioned adjacent to the third photodiode, the third axis being perpendicular to each of the first axis and the second axis.

13. The apparatus of claim 11, wherein principal planes of the birefringent crystal for each pixel cell of the array of pixel cells are parallel with each other.

14. The apparatus of claim 11, wherein:
a first principal plane of the birefringent crystal of a first pixel cell of the array of pixel cells is parallel with a first direction;
a second principal plane of the birefringent crystal of a second pixel cell of the array of pixel cells is parallel with a second direction; and
the first direction is perpendicular to the second direction.

15. The apparatus of claim 11, further comprising:
a processor configured to process outputs of the array of pixel cells to generate image frames; and
a display of a mobile device configured to display content based on the image frames.

16. The apparatus of claim 15, wherein the mobile device comprises a head-mounted display (HMID).

17. A method comprising:
refracting light incident light, using a microlens, to produce refracted light, wherein:
a first photodiode is positioned adjacent to a second photodiode in a semiconductor substrate along a first axis;
the microlens is positioned over a birefringent crystal along a second axis;
the second axis is orthogonal to the first axis;
the microlens has an asymmetric curvature along the first axis and an apex point of the asymmetric curvature is positioned over the first photodiode along the second axis;
separating the refracted light into a first component of light and a second component of light, using the birefringent crystal, wherein the birefringent crystal is positioned over the first photodiode and the second photodiode along the second axis;
detecting the first component of light using the first photodiode; and
detecting the second component of light using the second photodiode.

18. The method of claim 17, wherein the first component of light is a first linear polarization, and the second component of light is a second linear polarization orthogonal to the first linear polarization.

19. The method of claim 17, wherein:
the microlens is part of an optical element; and
the method further comprises generating image frames using an array of optical elements.

20. The method of claim 17, wherein:
detecting the first component of light using the first photodiode comprises measuring an ordinary ray component of light from the birefringent crystal; and
detecting the second component of light using the second photodiode comprises measuring an extraordinary ray component of light from the birefringent crystal.
